(19) United States
(12) Patent Application Publication
(10) Pub. No.: US 2026/0239935 A1
(43) Pub. Date: Aug. 13, 2026

(54) SILICON-ON-INSULATOR WAFER AND PREPARATION METHOD THEREFOR

(71) Applicant: INSTITUTE OF MICROELECTRONICS OF THE CHINESE ACADEMY OF SCIENCES, Beijing (CN)

(72) Inventors: Fanyu LIU, Beijing (CN); Bo LI, Beijing (CN); Tiexin ZHANG, Beijing (CN); Yang HUANG, Beijing (CN); Siyuan CHEN, Beijing (CN)

(73) Assignee: INSTITUTE OF MICROELECTRONICS OF THE CHINESE ACADEMY OF SCIENCES, Beijing (CN)

(21) Appl. No.: 19/155,866

(22) PCT Filed: May 23, 2024
(86) PCT No.: PCT/CN2024/094949

§ 371 Date: Aug. 12, 2025

(30) Foreign Application Priority Data
Dec. 25, 2023 (CN) 202311799582.X

(51) Int. Cl. H10P 90/00; H10D 86/00

(52) U.S. Cl. CPC H10P 90/1916; H10D 86/201

(57) ABSTRACT

The present invention provides a novel silicon-on-insulator wafer and a preparation method therefor. According to the present invention, the preparation method for a novel silicon-on-insulator wafer comprises the following steps: S1: preparing a TRL or porous silicon on and injecting hydrogen into a silicon wafer to form a hydrogen-injected silicon wafer; S2: growing SiO₂ as BOX2 on a substrate, and flipping the hydrogen-injected silicon wafer over to undergo low-temperature bonding with BOX2; S3: after high-temperature stripping, growing SiO₂ as BOX1 on the TRL or porous silicon; and S4: injecting hydrogen into the silicon wafer, then flipping the silicon wafer over to undergo low-temperature bonding with BOX1, and, after high-temperature stripping, forming SOI to obtain a novel silicon-on-insulator wafer. The novel silicon-on-insulator wafer of the present invention has lower back gate leakage.

This application is the US national phase of International application No. PCT/CN2024/094949, filed on May 23, 204, which claims priority of the Chinese patent application No. 202311799582.X filed on Dec. 25, 2023, both contents of which are incorporated herein by reference in their entireties.

### TECHNICAL FIELD

The present disclosure relates to the technical field of Silicon-On-Insulator wafers, and in particular to a novel Silicon-On-Insulator wafer and a preparation method thereof.

### BACKGROUND

The existing radio frequency circuit structure is shown in FIG. 1. When a bias voltage is applied to a back gate, there is a large leakage current between a trap rich layer (TRL) on an active region side and a back gate region formed by doping TRL in the radio frequency circuit, which seriously affects the regulation ability of the back gate.

In addition, an SOI (Silicon-On-Insulator) used for a preparation of the radio frequency circuit is a Buried Oxide Layer (BOX) grown between a top silicon and a back substrate through a deposition process. However, SiO₂ grown through the deposition process has disadvantages such as poor step coverage, low surface flatness and slow yield.

In view of this, the present disclosure is proposed.

### SUMMARY

The present disclosure aims to provide a novel Silicon-On-Insulator wafer and a preparation method thereof, and the novel Silicon-On-Insulator wafer has a capability of lower back gate leakage.

The present disclosure provides a preparation method for a novel Silicon-On-Insulator wafer, comprising following steps:
S1, preparing TRL or porous silicon on a silicon wafer and implanting hydrogen to form a hydrogen-implanted silicon wafer;
S2, growing SiO₂ on a substrate to form BOX2, and inverting (flipping over) the hydrogen-implanted silicon wafer and bonding the hydrogen-implanted silicon wafer with the BOX2 at a low temperature;
S3, exfoliating at a high temperature, then growing SiO₂ on the TRL or porous silicon to form BOX1;
S4: implanting hydrogen into a silicon wafer, then inverting the silicon wafer and bonding the silicon wafer with the BOX1 at a low temperature, and exfoliating at a high temperature to form SOI, to prepare a novel Silicon-On-Insulator wafer.

In an implementation, step S1 comprises: growing polysilicon on a silicon wafer by low pressure chemical vapor deposition (LPCVD) to form TRL, and then implanting hydrogen to form a hydrogen-implanted silicon wafer.

Specifically, a temperature of LPCVD is 600° C. to 650° C. and a time of LPCVD is 20 to 60 minutes.

The growth thickness of polysilicon is related to the growth time.

In another implementation, step S1 comprises: firstly, implanting hydrogen into a silicon wafer, then growing monocrystalline silicon on the silicon wafer that has been implanted hydrogen, and electrolyzing the monocrystalline silicon into porous silicon by electrolysis to form a hydrogen-implanted silicon wafer.

Specifically, CVD epitaxial process is adopted to grow monocrystalline silicon. The CVD epitaxial process comprises: firstly, gasifying Si in the silicon wafer into gaseous SiH₄ by reacting with H₂ at a high temperature of 200° C. to 500° C., then reacting gaseous SiH₄ with oxygen at a high temperature of 550° C. to 650° C. to generate monocrystalline silicon and H₂, wherein the monocrystalline silicon is deposited on a surface of the silicon wafer.

An electrolyte used for the electrolyzing is composed of hydrofluoric acid with a mass concentration of 40% and dimethylformamide with a mass concentration of 40%, a volume ratio of hydrofluoric acid to dimethylformamide is 1:(1.5 to 2.5), and the electrolyzing comprises: applying a bias voltage at a room temperature without the help of illumination, so that a current density reaches 60 to 70 mA/cm². The longer the corrosion time, the larger the aperture and depth. It may be set reasonably according to the actual needs.

In addition, in step S1, when implanting hydrogen, a hydrogen implantation dosage is 6×10¹⁶ to 9×10¹⁶ ions/cm², a hydrogen implantation energy is 10 to 80 keV, and a hydrogen implantation depth is 0.2 to 0.8 μm. The relationship between the hydrogen implantation energy and the hydrogen implantation depth is approximately linear, and the relationship between the hydrogen implantation energy and the hydrogen implantation depth is as shown in FIG. 4.

In step S2, SiO₂ may be grown in a conventional way, such as a deposition process. The deposition process comprises: firstly, reacting Si in the substrate with H₂ at 500° C. to 900° C. to generate gaseous SiH₄, and then reacting gaseous SiH₄ with oxygen at 500° C. to 900° C. to generate SiO₂ which is deposited on a surface of the substrate.

Preferably, SiO₂ is grown by a thermal oxidation, and the thermal oxidation is carried out in a vertical oxidation furnace, wherein a thermal oxidation temperature is 700° C. to 1000° C. The thermal oxidation is to expose a substrate to an oxygen-rich environment of the vertical oxidation furnace, and the Si in the substrate is thermally oxidized at high temperature to generate SiO₂. When the thermal oxidation temperature is 700° C., the relationship between the thermal oxidation time and the oxide layer thickness is as shown in FIG. 5.

In addition, in step S2, the silicon wafer and the substrate are subjected to a hydrophilic treatment before the bonding at the low-temperature. The hydrophilic treatment is to soak silicon wafer and substrate in water, and the water adsorbed on the surface of silicon wafer and the substrate destroys Si—O—Si bond on the surface of the silicon wafer, which forms OH bond with water. After the hydrophilic treatment, the silicon wafer and the substrate each formed with OH bond are polymerized at the bonding temperature of 120-150° C. to form a bonding.

In step S3, a temperature of the exfoliating at the high temperature is 500° C. to 600° C. TRL or porous silicon is left after the exfoliating at the high temperature. Subsequently, SiO₂ may be grown on the TRL or porous silicon by adopting the above deposition process or thermal oxidation method.

In step S4, when implanting hydrogen, a hydrogen implantation dosage is 6×10¹⁶ to 9×10¹⁶ ions/cm², a hydrogen implantation energy is 10 to 80 keV, and a hydrogen implantation depth is 0.2 to 0.8 μm.

Both the silicon wafer and the substrate are subjected to a hydrophilic treatment before the bonding at the low temperature (also referred as “low-temperature bonding”). After the bonding at the low temperature, an exfoliating is carried out at a high temperature of 500° C. to 600° C. After the hydrogen implantation, the part rich in hydrogen ions in the upper layer of the bonded hydrogen-implanted silicon wafer were blistered at a high temperature, so that the area above the blistering is exfoliated.

The present disclosure also provides a novel Silicon-On-Insulator wafer, which is manufactured according to the above preparation method.

Specifically, the novel Silicon-On-Insulator wafer comprises a substrate, BOX2 arranged on the substrate, TRL or porous silicon arranged on the BOX2, BOX1 arranged on the TRL or porous silicon, and SOI arranged on the BOX1.

The present disclosure provides a novel Silicon-On-Insulator wafer. The novel RFSOI wafer structure with a low substrate leakage has a capability of lower back gate leakage. In addition, the preparation method of the present disclosure can further prepare BOX1 and BOX2 by a thermal oxidation, thereby forming an interface with less interface trap charges and less fixed charges, so that the bonding surface is smoother, flatter and more uniform.

### BRIEF DESCRIPTION OF DRAWINGS

In order to illustrate the specific implementations of the present disclosure or the technical solution in the prior art more clearly, the drawings needed to be used in the description of the specific implementations or the prior art will be briefly introduced below. Obviously, the drawings in the following description are some implementations of the present disclosure. For those skilled in the art, other drawings can be obtained based on these drawings without creative work.

FIG. 1 is a schematic structural diagram of an existing radio frequency circuit;

FIG. 2 is a process flowchart of manufacturing a novel Silicon-On-Insulator wafer of Embodiment one;

FIG. 3 is a schematic structural diagram of the novel Silicon-On-Insulator wafer of Embodiment one;

FIG. 4 is a graph indicating the relationship between a hydrogen implantation depth and a hydrogen implantation energy;

FIG. 5 is a graph indicating the relationship between an oxidation time and an oxidation thickness in a thermal oxidation process;

FIG. 6 is a process flowchart of manufacturing a novel Silicon-On-Insulator wafer of Embodiment two;

FIG. 7 is a schematic diagram for preparation porous silicon by electrolysis;

FIG. 8 is a schematic structural diagram of a Silicon-On-Insulator wafer of Comparative Example one.

### DESCRIPTION OF EMBODIMENTS

It should be indicated that the following detailed descriptions are all exemplary and are intended to provide further explanation for the present disclosure. Unless otherwise specified, all technical and scientific terms used herein have the same meaning as commonly understood by those skilled in the art to which the present disclosure belongs.

It should be noted that the terms used here is only for describing specific implementations, and is not intended to limit exemplary implementations according to the present disclosure. As used herein, the singular form also includes the plural form unless the context clearly indicates otherwise. Further, it should also be understood that when the terms “contain” and/or “comprise (include)” are used in this disclosure, they specify the presence of features, steps, operations, devices, components and/or combinations thereof.

The technical solution of the present disclosure will be described clearly and completely with reference to embodiments. Obviously, the described embodiments are a part of embodiments of the present disclosure, but not all the embodiments. Based on the embodiments in the present disclosure, all other embodiments obtained by those skilled in the art without creative work should fall within the protection scope of the present disclosure.

### Embodiment One

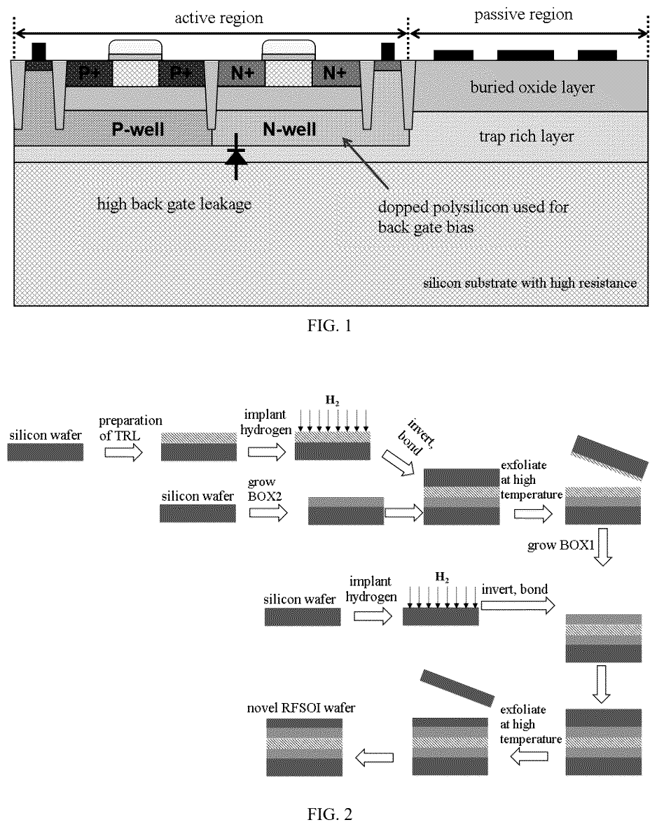

Referring to FIG. 2, a preparation method of a novel Silicon-On-Insulator wafer of this embodiment includes the following steps.
S1: preparing TRL and implanting hydrogen

Firstly, polysilicon was grown on a silicon wafer by LPCVD to form TRL, and the conditions of LPCVD included: a temperature of 625° C., a time of 40 min.

Then, hydrogen was implanted into the silicon wafer growing with polysilicon to form a hydrogen-implanted silicon wafer. Here, a hydrogen implantation dosage was 6×10¹⁶ ions/cm², a hydrogen implantation energy was 10 keV, and a hydrogen implantation depth was 0.2 μm. The relationship between the hydrogen implantation depth and the hydrogen implantation energy is indicated in FIG. 4.
S2: preparing BOX2, and bonding at a low temperature

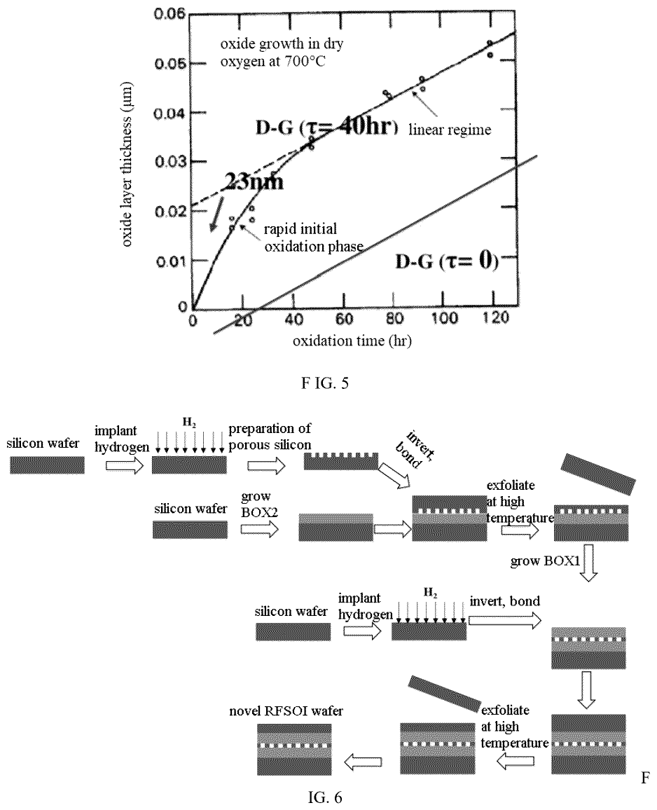

A substate (silicon wafer, referred to as SUB) was placed in an oxygen-rich environment of a vertical oxidation furnace, so that Si in the substrate was thermally oxidized at 700° C. to generate SiO₂ to form BOX2. The thermal oxidation time and the oxidation thickness are obtained according to FIG. 5.

Then, the hydrogen-implanted silicon wafer in step S1 and the substrate in step S2 were soaked in water for a hydrophilic treatment, and then were bonded at a low temperature of 120° C. after the hydrophilic treatment.
S3: exfoliating at a high temperature and preparing BOX1

The substrate that had been subjected to the low-temperature bonding in step S2 was exfoliated at a high temperature of 500° C., and TRL was left after the high-temperature exfoliating.

Then, the substrate that had been subjected to the high-temperature exfoliating was placed in an oxygen-rich environment of a vertical oxidation furnace, so that Si in the substrate was thermally oxidized at 700° C. to generate SiO₂ to form BOX1. The thermal oxidation time and the oxidation thickness are obtained according to FIG. 5.
S4: implanting hydrogen, bonding at a low temperature and exfoliating at a high temperature

Hydrogen was implanted into another silicon wafer to form a hydrogen-implanted silicon wafer. Here, a hydrogen implantation dosage was 6×10¹⁶ ions/cm², a hydrogen implantation energy was 10 keV, and a hydrogen implantation depth was 0.2 μm. The relationship between the hydrogen implantation depth and the hydrogen implantation energy is indicated in FIG. 4.

The substrate after growing BOX1 in step S3 and the hydrogen-implanted silicon wafer in step S4 were soaked in water for a hydrophilic treatment, and then were bonded at a low temperature of 120° C. after the hydrophilic treatment.

The substrate that had been subjected to the low-temperature bonding was exfoliated at a high temperature of 500° C., and SOI was formed after the high-temperature exfoliating, so that a novel Silicon-On-Insulator wafer (i.e. a novel RFSOI) was prepared.

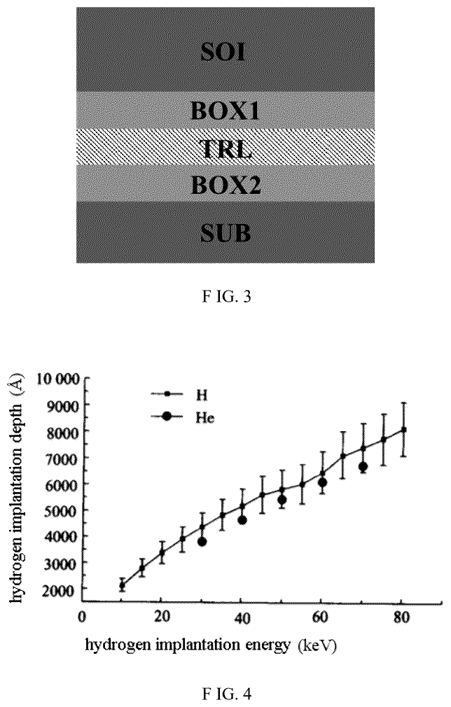

As shown in FIG. 3, the novel RFSOI structure prepared in this embodiment includes a substrate, BOX2 arranged on the substrate, TRL arranged on the BOX2, BOX1 arranged on the TRL, and SOI arranged on the BOX1. The novel RFSOI has a capability of lower back gate leakage.

### Embodiment Two

Referring to FIG. 6, a preparation method of a novel Silicon-On-Insulator wafer of this embodiment includes the following steps.
S1: implanting hydrogen and preparing porous silicon

Hydrogen was implanted into a silicon wafer. Here, a hydrogen implantation dosage was 9×10¹⁶ ions/cm², a hydrogen implantation energy was 80 keV, and a hydrogen implantation depth was 0.8 μm. The relationship between the hydrogen implantation depth and the hydrogen implantation energy is indicated in FIG. 4.

Monocrystalline silicon was grown through CVD epitaxial process. The CVD epitaxial process included: firstly, gasifying Si in the silicon wafer into gaseous SiH₄ by reacting with H₂ at a high temperature of 400° C., then reacting gaseous SiH₄ with oxygen at a high temperature of 600° C. to generate monocrystalline silicon and H₂, wherein the monocrystalline silicon was deposited on a surface of the silicon wafer.

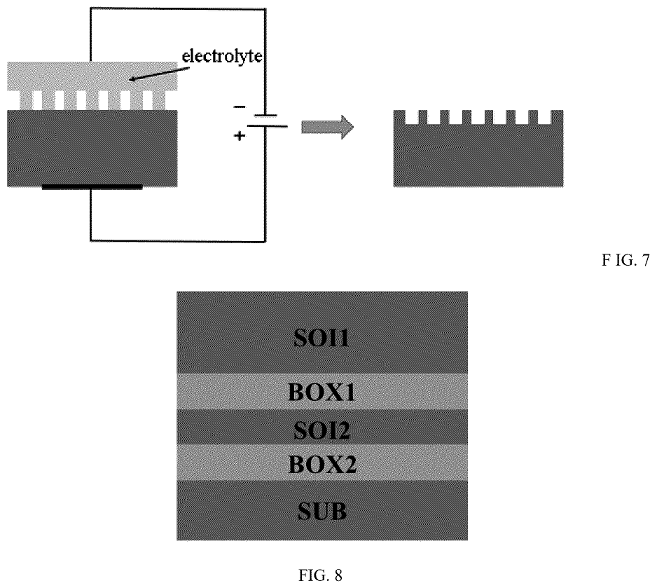

As shown in FIG. 7, the monocrystalline silicon was electrolyzed into porous silicon by electrolysis to form a hydrogen-implanted silicon wafer. Here, the electrolyte employed for the electrolyzing was composed of hydrofluoric acid with a mass concentration of 40% and dimethylformamide with a mass concentration of 40%, and the volume ratio of hydrofluoric acid to dimethylformamide was 1:2. A bias voltage was applied at a room temperature without the help of illumination, so that the current density reached 64 mA/cm².
S2: preparing BOX2, and bonding at a low temperature

A substate (silicon wafer, referred to as SUB) was placed in an oxygen-rich environment of a vertical oxidation furnace, so that Si in the substrate was thermally oxidized at 700° C. to generate SiO₂ to form BOX2. The thermal oxidation time and the oxidation thickness are obtained according to FIG. 5.

Then, the hydrogen-implanted silicon wafer in step S1 and the substrate in step S2 were soaked in water for a hydrophilic treatment, and then were bonded at a low temperature of 150° C. after the hydrophilic treatment.
S3: exfoliating at a high temperature and preparing BOX1

The substrate that had been subjected to the low-temperature bonding in step S2 was exfoliated at a high temperature of 600° C., and TRL was left after the high-temperature exfoliating.

Then, the substrate that had been subjected to the high-temperature exfoliating was placed in an oxygen-rich environment of a vertical oxidation furnace, so that Si in the substrate was thermally oxidized at 700° C. to generate SiO₂ to form BOX1. The thermal oxidation time and the oxidation thickness are obtained according to FIG. 5.
S4: implanting hydrogen, bonding at a low temperature and exfoliating at a high temperature

Hydrogen was implanted into another silicon wafer to form a hydrogen-implanted silicon wafer. Here, a hydrogen implantation dosage was 9×10¹⁶ ions/cm², a hydrogen implantation energy was 80 keV, and a hydrogen implantation depth was 0.8 μm. The relationship between the hydrogen implantation depth and the hydrogen implantation energy is indicated in FIG. 4.

The substrate after growing BOX1 in step S3 and the hydrogen-implanted silicon wafer in step S4 were soaked in water for a hydrophilic treatment, and then were bonded at a low temperature of 150° C. after the hydrophilic treatment.

The substrate that was subjected to the low-temperature bonding was exfoliated at a high temperature of 600° C., and SOI was formed after the high-temperature exfoliating, so that a novel Silicon-On-Insulator wafer (i.e. a novel RFSOI) was prepared.

The novel RFSOI structure prepared in this embodiment includes a substrate, BOX2 arranged on the substrate, porous silicon arranged on the BOX2, BOX1 arranged on the porous silicon, and SOI arranged on the BOX1. The novel RFSOI has a capability of lower back gate leakage.

### Comparative Example One

A Silicon-On-Insulator wafer structure of this Comparative Example is shown in FIG. 8, and the preparation steps are as follows.
S1: implanting hydrogen

Hydrogen was implanted into a silicon wafer to form a hydrogen-implanted silicon wafer. Here, a hydrogen implantation dosage was 6×10¹⁶ ions/cm², a hydrogen implantation energy was 10 keV, and a hydrogen implantation depth was 0.2 μm.
S2: preparing BOX2, and bonding at a low temperature

A substate (silicon wafer, referred to as SUB) was placed in an oxygen-rich environment of a vertical oxidation furnace, so that Si in the substrate was thermally oxidized at 700° C. to generate SiO₂ to form BOX2. The thermal oxidation time and the oxidation thickness are obtained according to FIG. 5.

Then, the hydrogen-implanted silicon wafer in step S1 and the substrate in step S2 were soaked in water for a hydrophilic treatment, and then were bonded at a low temperature of 120° C. after the hydrophilic treatment.
S3: exfoliating at a high temperature and preparing BOX1

The substrate that had been subjected to the low-temperature bonding in step S2 was exfoliated at a high temperature of 500° C. to form SOI2.

Then, the substrate that had been subjected to the high-temperature exfoliating was placed in an oxygen-rich environment of a vertical oxidation furnace, so that Si in the substrate was thermally oxidized at 700° C. to generate SiO₂ to form BOX1. The thermal oxidation time and the oxidation thickness are obtained according to FIG. 5.
S4: implanting hydrogen, bonding at a low temperature and exfoliating at a high temperature

Hydrogen was implanted into another silicon wafer to form a hydrogen-implanted silicon wafer. Here, a hydrogen implantation dosage was 6×10¹⁶ ions/cm², a hydrogen implantation energy was 10 keV, and a hydrogen implantation depth was 0.2 μm. The relationship between the hydrogen implantation depth and the hydrogen implantation energy is indicated in FIG. 4.

The substrate after growing BOX1 in step S3 and the hydrogen-implanted silicon wafer in step S4 were soaked in water for a hydrophilic treatment, and then were bonded at a low temperature of 120° C. after the hydrophilic treatment.

The substrate that had been subjected to the low-temperature bonding was exfoliated at a high temperature of 500° C., and SOI was formed after the high-temperature exfoliating, so that a Silicon-On-Insulator wafer was prepared.

The Silicon-On-Insulator wafer prepared in this comparative example includes a substrate, BOX2 arranged on the substrate, SOI2 arranged on the BOX2, BOX1 arranged on the SOI2, and SOI1 arranged on the BOX1. The Silicon-On-Insulator wafer has a large back gate leakage, which seriously affects the back gate control ability.

### Comparative Example Two

Except that BOX2 and BOX1 were prepared through a deposition process, the others were basically the same as those of Comparative Example one. The deposition process steps are as follows: firstly, Si in the substrate reacted with H₂ at 700° C. to generate gaseous SiH₄, and then the gaseous SiH₄ reacted with oxygen at 700° C. to generate SiO₂, which was deposited on a surface of the substrate.

The results indicate that BOX2 and BOX1 prepared through a deposition process have poor step coverage and low surface flatness. However, BOX2 and BOX1 prepared by a thermal oxidation method can form an interface with less interface trap charges and less fixed charges, so that the bonding surface is smoother, flatter and more uniform.

Finally, it should be explained that the above embodiments are only used to illustrate the technical solution of the present disclosure, but not to limit it. Although the present disclosure has been described in detail with reference to the above embodiments, it should be understood by those skilled in the art that the technical solutions described in the above embodiments may still be modified, or some or all of its technical features may be replaced by equivalents. However, these modifications or replacements do not make the essence of the corresponding technical solutions deviate from the scope of the technical solutions of various embodiments of the present disclosure.

1. A preparation method for a novel Silicon-On-Insulator wafer, comprising following steps:
S1: preparing TRL or porous silicon on a silicon wafer and implanting hydrogen to form a hydrogen-implanted silicon wafer;
S2: growing SiO₂ on a substrate to form BOX2, and inverting the hydrogen-implanted silicon wafer and bonding the hydrogen-implanted silicon wafer with the BOX2 at a low temperature;
S3: exfoliating at a high temperature, then growing SiO₂ on the TRL or porous silicon to form BOX1;
S4: implanting hydrogen into a silicon wafer, then inverting the silicon wafer and bonding the silicon wafer with the BOX1 at a low temperature, and exfoliating at a high temperature to form SOI, to prepare a novel Silicon-On-Insulator wafer.

2. The preparation method according to claim 1, wherein step S1 comprises: growing polysilicon on a silicon wafer by LPCVD to form TRL, and then implanting hydrogen to form a hydrogen-implanted silicon wafer.

3. The preparation method according to claim 2, wherein a temperature of LPCVD is 600° C. to 650° C. and a time of LPCVD is 20 to 60 minutes.

4. The preparation method according to claim 1, wherein step S1 comprises: firstly, implanting hydrogen into a silicon wafer, then growing monocrystalline silicon on the silicon wafer that has been implanted hydrogen, and electrolyzing the monocrystalline silicon into porous silicon by electrolysis to form a hydrogen-implanted silicon wafer.

5. The preparation method according to claim 4, wherein the monocrystalline silicon is grown through CVD epitaxial process; and the CVD epitaxial process comprises: firstly, gasifying Si in the silicon wafer into gaseous SiH₄ by reacting with H₂ at a high temperature of 200° C. to 500° C., then reacting gaseous SiH₄ with oxygen at a high temperature of 550° C. to 650° C. to generate monocrystalline silicon and H₂, wherein the monocrystalline silicon is deposited on a surface of the silicon wafer.

6. The preparation method according to claim 4, wherein an electrolyte used for the electrolyzing is composed of hydrofluoric acid with a mass concentration of 40% and dimethylformamide with a mass concentration of 40%, a volume ratio of hydrofluoric acid to dimethylformamide is 1:(1.5 to 2.5), and the electrolyzing comprises: applying a bias voltage at a room temperature without the help of illumination, so that a current density reaches 60 to 70 mA/cm².

7. The preparation method according to claim 1, wherein when implanting hydrogen, a hydrogen implantation dosage is 6×10¹⁶ to 9×10¹⁶ ions/cm², a hydrogen implantation energy is 10 to 80 keV, and a hydrogen implantation depth is 0.2 to 0.8 μm.

8. The preparation method according to claim 1, wherein SiO₂ is grown by a thermal oxidation, and the thermal oxidation is carried out in a vertical oxidation furnace, wherein a thermal oxidation temperature is 700° C. to 1000° C.

9. The preparation method according to claim 1, wherein the silicon wafer and the substrate are subjected to a hydrophilic treatment before the bonding at the low temperature, and a temperature of the bonding at the low temperature is 120° C. to 150° C.; a temperature of the exfoliating at the high temperature is 500° C. to 600° C.

10. A novel Silicon-On-Insulator wafer, wherein the novel Silicon-On-Insulator wafer is manufactured by the preparation method according to claim 1, and comprises a substrate, BOX2 arranged on the substrate, TRL or porous silicon arranged on the BOX2, BOX1 arranged on the TRL or porous silicon, and SOI arranged on the BOX1.
